(19) United States
(12) Patent Application Publication
(10) Pub. No.: US 2014/0191772 A1
(43) Pub. Date: Jul. 10, 2014

(54) DIFFERENTIAL CURRENT SENSOR

(71) Applicant: Ullrich Hetzler, Dillenburg-Oberscheld (DE)

(72) Inventor: Ullrich Hetzler, Dillenburg-Oberscheld (DE)

(73) Assignee: ISABELLENHUETTE HEUSLER GMBH & CO. KG, Dillenburg (DE)

(21) Appl. No.: 13/878,600

(22) PCT Filed: Aug. 6, 2012
(86) PCT No.: PCT/EP12/03357

§ 371 Date: Apr. 10, 2013

(30) Foreign Application Priority Data
Sep. 9, 2011 (DE) 10 2011 113 002.4

(51) Int. Cl. G01R 19/10

(52) U.S. Cl. CPC G01R 19/10
USPC 324/705

(57) ABSTRACT

The invention relates to a differential current sensor for measuring a differential current (ΔI) between an electric current (IH) through a delivery conductor (H) and an electric current (IR) through a return conductor (R), with two low-ohmic current-measuring resistors (RH, RL) for measuring the currents (IH, IR) in the delivery conductor (H) and return conductor (R) and two measuring devices (MEH, MEL) with a measuring transducer for measuring the voltage drops (UH, UL) over the two current-sense resistors (RH, RL) in each case, and also with two voltage references (U_{REFH}, U_{REFL}) for calibrating the measuring devices (MEH, MEL). It is suggested that the two measuring transducers successively measure both the voltage drop (UH) over the respective current-sense resistor (RH) and the associated voltage reference (U_{REFH}, U_{REFL}).

The invention relates to a differential current sensor, in particular for a direct-current power supply system.

A differential current sensor of this type is known from WO 00/00834 A1, which differential current sensor can be used, for example, in a single-phase alternating-current power supply system, in order to measure the electric currents in the delivery and return conductors, so that a differential current can be calculated therefrom, in order to be able to detect a fault. The actual current measurement here takes place in accordance with the four-wire technology, which is known per se, by means of low-ohmic current-sense resistors which are arranged in the delivery conductor and in the return conductor respectively, the electric currents to be measured flow through them, so that the voltage drop over the current-sense resistors forms a measure for the respective current. This known differential current sensor additionally has an ASIC (ASIC: Application Specific Integrated Circuit) which calculates the voltage over the two current-sense resistors in the delivery and return conductors and calculates the differential current therefrom. Furthermore, this known differential current sensor allows a calibration of the voltage measurements at the two current-sense resistors in that the ASIC measures one voltage reference in each case at the ground side and voltage side, which is provided by a voltage divider between the delivery conductor and return conductor. The measurement of the voltage references by the ASIC here takes place within the ASIC by means of separate measuring transducers.

The unsatisfactory calibration, which has proven not particularly accurate, is disadvantageous in the previously described known differential current sensor.

Reference is also made to US 2005/0248351 A1 concerning the prior art. This printed publication discloses a measuring circuit for measuring a battery voltage, wherein a measuring transducer measures the voltage drop over a current-sense resistor. The current-sense resistor can here optionally be connected to the battery or to a voltage reference. The measuring transducer itself however always measures the voltage drop over the current-sense resistor and cannot be connected to the voltage reference. A complete calibration is not possible in this manner.

Reference is also made to DE 10 2010 038 851 A1, DE 20 2010 005 756 U1 and DE 10 2004 062 655 A1 concerning the prior art.

The invention is therefore based on the object of improving accordingly the known differential current sensor described above.

This object is achieved by a differential current sensor according to the invention in accordance with the main claim.

The invention is based on the technical insight that the unsatisfactory results during calibration in the known differential current sensor originate from the fact that the voltage reference on the one hand and the voltage drop over the current-sense resistor on the other hand are detected by separate measuring transducers. This is disadvantageous, because measurement errors of the individual measuring transducers cannot be compensated in this manner in the context of the calibration. The invention therefore comprises the general technical teaching that in the differential current sensor according to the invention, the voltage reference and the voltage drop over the current-sense resistor are measured by the same measuring transducer, specifically both on the voltage side (“high side”) and on the ground side (“low side”). The two voltage-side or ground-side measuring transducers therefore measure the respective voltage reference and the voltage drop over the respective current-sense resistor successively in quick succession in the differential current sensor according to the invention.

In a preferred exemplary embodiment of the invention, the voltage reference for the calibration is provided by means of a voltage divider—as in the known differential current sensor according to WO 00/00834 A1 described at the beginning—which is connected between the delivery conductor and the return conductor. Here, a first voltage reference for the calibration of the voltage-side current measurement is formed by means of a first voltage tapping point at the voltage divider, whilst a second voltage reference for the calibration of the ground-side current measurement is formed by means of a second voltage tapping point at the voltage divider.

In the preferred exemplary embodiment, the voltage divider is dimensioned such that the first voltage drop over the first current-sense resistor is of the same order of magnitude as the first voltage reference. Furthermore, the voltage divider is preferably also dimensioned in such a manner that the second voltage drop over the second current-sense resistor is of the same order of magnitude as the second voltage reference. For example, these voltage values may lie in the region of 30 mV. This approximate matching of the voltage values of the voltage references on the one hand and the voltages over the current-sense resistors on the other hand is advantageous, because in this case the respective measuring transducer and, if appropriate, an additional pre-amplifier can successively measure the voltage reference and the voltage drop over the respective current-sense resistor without internal settings in the measuring transducer or the pre-amplifier having to be changed.

In the preferred exemplary embodiment of the invention, the voltage divider has a series circuit made up of a voltage-side first resistor (e.g. R1=100Ω), a central second resistor (e.g. R2=2 MΩ) and a ground-side third resistor (e.g. R3=100Ω). The central second resistor here preferably has a substantially higher resistance value than the voltage-side first resistor and than the ground-side third resistor. The first voltage reference for the voltage-side calibration is here preferably provided by means of a first voltage tapping point between the voltage-side resistor of the voltage divider and the central resistor of the voltage divider. The second voltage reference for the calibration of the ground-side current measurement is by contrast preferably formed by means of a second voltage tapping point between the ground-side third resistor and the central resistor of the voltage divider.

Preferably, the resistance value at the voltage-side first resistor of the voltage divider and at the ground-side third resistor of the voltage divider essentially shows the same temperature dependence. This is advantageous for a temperature independence during calibration and during operation, which is as high as possible. For example, metal-film resistors, which originate from the same batch and therefore have approximately the same temperature dependence, can be used to build the voltage divider. Furthermore, small differences in temperature coefficient can also be detected during the calibration and computationally eliminated. Furthermore, it is to be mentioned that the two outer resistors of the voltage divider in this arrangement are only loaded very slightly so that very good long-term stability is to be expected.

The temperature independence and the accuracy of the high-ohmic central resistor of the voltage divider by contrast play no or only a slight role in the differential current measurement. Preferably, the differential current sensor according to the invention also allows a total voltage measurement however, i.e. a measurement of the voltage between delivery conductor and return conductor, wherein good long-term stability and good synchronization of the temperature coefficient is also necessary for the high-ohmic central resistor of the voltage divider. Both requirements can be realized ideally with a network produced from a homogeneous resistance material (e.g. thin film) on ceramic, wherein the necessary dielectric strength is also present.

Furthermore, the differential current sensor according to the invention preferably has an electronic evaluation unit which is connected to the two measuring devices for measuring the voltage drop and determines the differential current as a function of the two voltage drops over the voltage-side and ground-side current-sense resistors respectively.

To achieve a measurement accuracy which is as high as possible, the voltage measurement should take place over the current-sense resistors on the voltage side (“high side”) and on the ground side (“low side”) at the same time. The evaluation unit therefore preferably transmits a triggering signal to the two voltage-side or ground-side measuring devices, in order to trigger the voltage measurement, so that the voltage measurement takes place on the ground side and voltage side simultaneously.

The data transmission between the measuring devices on the one hand and the evaluation unit on the other hand preferably takes place by means of galvanically separated data lines, e.g. optocouplers.

The accuracy of the measurement can be increased further in that the two current-sense resistors are connected to one another by means of an electrically insulating, but thermally conductive heat bridge, in order to prevent temperature differences between the two current-sense resistors.

The disturbing influence of temperature fluctuations cannot be inhibited completely however in the differential current sensor according to the invention and is therefore preferably compensated computationally in the differential current sensor according to the invention.

An additional thermal source of disruption exists in thermoelectric potentials in the measurement circuit (current-sense resistor and measuring device), which originate from temperature differences over the current-sense resistors. As the measuring device fundamentally cannot differentiate between a thermoelectric potential and a voltage drop created by means of a current flow, the thermoelectric potential must be determined indirectly continuously. To this end, the differential current sensor according to the invention preferably has thermocouples which measure the temperature difference over the current-sense resistors. The resulting thermoelectric potential is then calculated as a function of the measured temperature difference, wherein this calculation can take place for example in the respective measuring device or in the evaluation unit (e.g. ASIC). A corresponding compensation then takes place during the current measurement, wherein the compensation can take place for example in the measuring device or in the evaluation unit.

A further disturbing temperature influence consists in the fact that the resistance value of the current-sense resistors also fluctuates slightly as a function of the temperature in current-sense resistors with high temperature stability. The differential current sensor according to the invention therefore preferably enables a compensation of these temperature-related fluctuations of the resistance value of the current-sense resistors. To this end, temperature sensors are preferably provided, which measure the temperature of the respective current-sense resistor. Subsequently, the temperature-related change of the resistance value of the current-sense resistors is calculated by the measuring device or by the evaluation unit and taken into account in a compensating manner during the current measurement.

For a high measurement accuracy, it is furthermore important that the two current-sense resistors on the ground side (“low side”) and voltage side (“high side”) have the same resistance value and also show the same temperature dependence.

It has already been mentioned previously that the differential current sensor according to the invention measures the voltage reference and the voltage drop over the current-sense resistor successively via the same measurement path, i.e. with the same measuring transducer. The measuring devices on the voltage side and ground side therefore preferably have a multiplexer which successively measures the voltage drop over the respective current-sense resistor and the associated voltage reference.

Furthermore, the multiplexer preferably also measures the other values, such as for example the first or second temperature difference and the first or second temperature.

Further, it is to be mentioned that the functionalities of the previously described measuring devices and the evaluation unit are preferably realized in separate electronic components. There is, however, in the context of the invention also the possibility that these functionalities are integrated in one or a plurality of components (e.g. ASICs).

It is furthermore to be mentioned that the differential current sensor according to the invention is particularly well suited for the measurement of differential currents (fault currents) in direct-current power supply systems, such as for example in motor vehicle electrical systems. The differential current sensor according to the invention is however also suitable for alternating-current power supply systems, in particular for single-phase power supply systems.

Finally, it is also to be mentioned that in the preferred exemplary embodiment the differential current sensor according to the invention outputs not only the differential current, but also absolute values, such as for example the temperature differences over the current-sense resistors, the temperatures of the current-sense resistors, the total voltage between delivery conductor and return conductor and/or the total current.

Other advantageous developments of the invention are characterized in the subclaims or are explained in more detail below together with the description of the preferred exemplary embodiment of the invention on the basis of the figures. The figures show as follows:

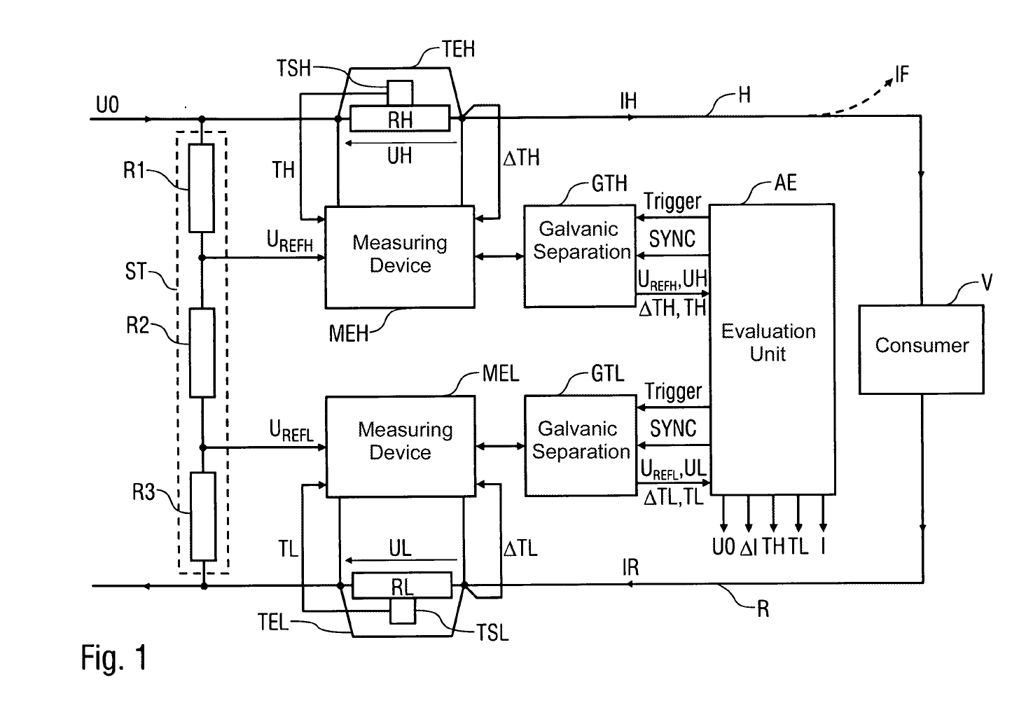

FIG. 1 a schematic block circuit diagram of a differential current sensor according to the invention, and

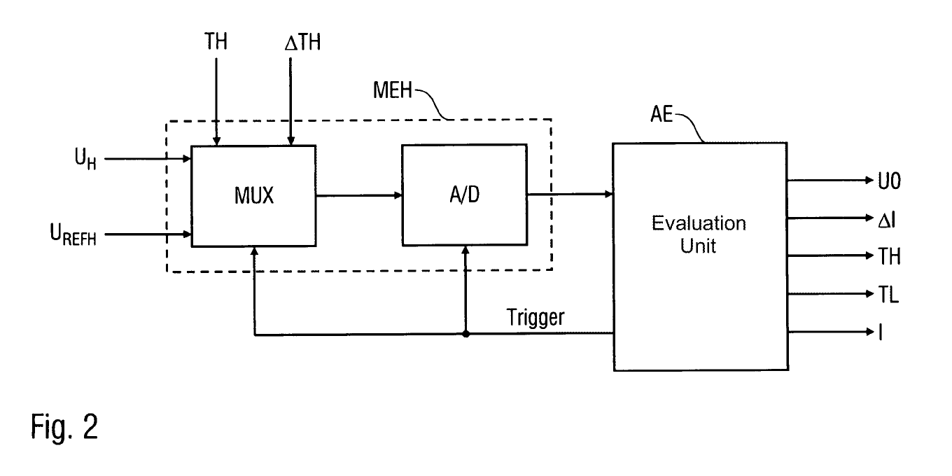

FIG. 2 a simplified block circuit diagram of the voltage-side measuring device from FIG. 1, wherein the ground-side measuring device is built accordingly.

The drawings show a schematic illustration of a differential current sensor according to the invention, which can for example be used in a single-phase direct-current power supply network in order to measure a differential current ΔI.

The direct-current power supply network is here only illustrated schematically and essentially consists of a delivery conductor H, a return conductor R and a schematically illustrated consumer V, wherein an electric current IH flows through the delivery conductor H to the consumer V, whilst a corresponding electric current IR flows back through the return conductor R.

In the case of flawless operation, the electric current IH through the delivery conductor H corresponds exactly to the electric current IR through the return conductor R.

In the event of a fault however, a fault current IF can flow off from the delivery conductor H, for example in the case of a short circuit to ground or in the case of leak currents to ground. In the event of such a fault, the electric currents IH, IR in the delivery conductor H and in the return conductor R differ by the differential current ΔI, so that then under certain circumstances counteractive measures (e.g. emergency shutdown) must be taken.

The differential current sensor according to the invention therefore makes it possible to measure the voltage-side current IH in the delivery conductor H and measure the ground-side current IR in the return conductor R, wherein the current measurement takes place in accordance with the four-wire technology which is known per se. To this end, a low-ohmic current-sense resistor RH is arranged in the delivery conductor H and a corresponding further low-ohmic current-sense resistor RL is located in the return conductor R.

The two low-ohmic current-sense resistors RH, RL can for example be current-sense resistors as are described in EP 0 605 800 A1, so that the content of this patent application is to be incorporated fully in the present description with respect to the manner of production and the structure of the low-ohmic current-sense resistors RH, RL.

To measure a voltage drop UH over the voltage-side current-sense resistor RH, a measuring device MEH is provided, just as a measuring device MEL is provided for measuring a voltage drop UL over the ground-side current-sense resistor RL.

The voltage-side measuring device MEH is connected via a galvanic separation GTH (e.g. optocoupler) to an evaluation unit AE, wherein the evaluation unit AE is connected via a further galvanic separation GTL (e.g. optocoupler) to the ground-side measuring device MEL. The evaluation unit AE receives the voltage drops UH, UL, which are measured by the two measuring devices MEH, MEL over the voltage-side current-sense resistor RH and over the ground-side current-sense resistor RL respectively, by means of the two galvanic separations GTH, GTL. The data transmission by the galvanic separations GTH, GTL here takes place in digital form.

Furthermore, the differential current sensor according to the invention also allows a calibration by means of a voltage divider ST, which is connected between the delivery conductor H and the return conductor R, wherein the voltage divider ST consists of three resistors R1=100Ω, R2=2 MΩ, R3=100Ω.

A voltage tapping point, which provides a voltage reference U_{REFH} for calibration, is located here between the resistor R1 and the resistor R2 of the voltage divider. The measuring device MEH successively measures the voltage drop UH over the current-sense resistor RH and the voltage reference U_{REFH} by means of a multiplexer MUX. It is important here that this measurement takes place via the same measurement path, as a result of which the calibration is substantially more accurate than in the case of the conventional differential current sensor according to WO 00/00834 A1 described at the beginning. The measuring device MEH then transmits the measured voltage reference U_{REFH} via the galvanic separation GTH to the evaluation unit AE.

A further voltage tapping point, which provides a ground-side voltage reference U_{REFL} for calibration of the measuring device MEL, is located here between the resistor R2 and the resistor R3 of the voltage divider ST. Also, a multiplexer MUX is provided in the measuring device MEL, which successively measures the voltage drop UL over the current-sense resistor RL and the voltage reference U_{REFL} via the same measurement path. An analog/digital converter is located behind the multiplexer MUX in the two measuring devices MEH, MEL, so that the measured voltage values are transmitted as digital signals to the evaluation unit AE.

Furthermore, the differential current sensor according to the invention also allows a compensation of thermoelectric potentials, which arise due to temperature differences over the current-sense resistors RH, RL. To this end, the differential current sensor according to the invention has two thermocouples TEH, TEL which measure a temperature difference ΔTH over the voltage-side current-sense resistor RH and a temperature difference ΔTL over the ground-side current-sense resistor RL respectively. This measurement of the temperature differences ΔTH, ΔTL likewise takes place by means of the multiplexer MUX of the respective measuring device MEH, MEL.

Furthermore, the differential current sensor according to the invention also allows a compensation of temperature-related fluctuations of the resistance value of the two current-sense resistors RH, RL. To this end, temperature sensors TSH and TSL are provided, which measure the temperature TH of the voltage-side current-sense resistor RH and the temperature TL of the ground-side current-sense resistor RL. This measurement of the temperatures TH, TL likewise takes place by means of the multiplexer MUX of the respective measuring device MEH, MEL.

The differential current ΔI is then calculated in the evaluation unit AE as a function of the measured data in accordance with the following formula:

$$\begin{matrix}Δ I = IH - IR \\ = \frac{{UH}_{OHM}}{RH ( TH )} - \frac{{UL}_{OHM}}{RL ( TL )} \\ = \frac{UH - {UH}_{THERMO} ( Δ TH )}{RH ( TH )} - \frac{UL - {UL}_{THERMO} ( Δ TL )}{RL ( TL )}\end{matrix}$$

with:
IH: Current through the delivery conductor H
IR: Current through the return conductor R
UH_{OHM}: Ohmic voltage drop over the voltage-side current-sense resistor RH
UL_{OHM}: Ohmic voltage drop over the ground-side current-sense resistor RL
UH_{THERMO}: Thermoelectric potential over the voltage-side current-sense resistor RH
UL_{THERMO}: Thermoelectric potential over the ground-side current-sense resistor RL
RH: Temperature-dependent resistance value of the voltage-side current-sense resistor RH
RL: Temperature-dependent resistance value of the ground-side current-sense resistor RH
ΔTH: Temperature difference over the voltage-side current-sense resistor RH
ΔTL: Temperature difference over the ground-side current sense resistor RL
TH: Temperature of the voltage-side current-sense resistor RH
TL: Temperature of the voltage-side current-sense resistor RL
UH: Measured voltage drop over the voltage-side current-sense resistor RH
UL: Measured voltage drop over the ground-side current-sense resistor RL.

The temperature-dependent characteristics of the resistance values RH(TH) and RL(TL) are here present as characteristic curves and are stored in the evaluation unit AE.

Furthermore, the temperature-dependent characteristics of the thermoelectric potentials UH_{THERMO}(ΔTH) and UL_{THERMO}(ΔTL) are present as characteristic curves and are stored in the evaluation unit AE.

It is further advantageous in the differential current sensor that the voltage references U_{REFH} and U_{REFL} respectively are of the same order of magnitude as the associated voltage drops UH and UL respectively. This is advantageous, because the measuring devices MEH and MEL respectively can then successively measure these voltage values without internal switching being required.

Furthermore, it is to be mentioned that the evaluation unit AE transmits a triggering signal to the two measuring devices MEH, MEL via the galvanic separations GTH, GTL, so that the voltage drops UH, UL over the two current-sense resistors RH, RL are measured virtually exactly isochronously which contributes to a high measurement accuracy.

Further, the evaluation unit AE in each case transmits a synchronization signal SYNC via the two galvanic separations GTH, GTL to the two measuring devices MEH, MEL in order to synchronize the measurements thereof exactly.

Furthermore, it is important that during the calibration, the voltage references U_{REFH}, U_{REFL} on the one hand and the respective voltage drops UH, UL are measured via the same measurement path, which likewise contributes to an improvement of the measurement accuracy.

It can furthermore be seen from the drawing that in addition to the differential current ΔI, the evaluation unit AE has further outputs for outputting a total current I, the temperatures TH, TL and a total voltage U0, which drops between the delivery conductor H and the return conductor R.

The invention is not limited to the previously described preferred exemplary embodiment. Instead, a plurality of variants and modifications are also possible, which also make use of the concept of the invention and thus fall within the scope of protection. Furthermore the invention also claims protection for the subject-matter and the features of the subclaims independently of the claims to which they refer. For example, the technical idea of temperature compensation in a differential current sensor is of separate importance, which is worthy of protection, and may be protected independently of the other features.

### LIST OF REFERENCE SIGNS

ΔI Differential current
ΔTH Temperature difference over current sense resistor RH
ΔTL Temperature difference over current sense resistor RL
AE Evaluation unit
GTH Galvanic separation on the voltage side
GTL Galvanic separation on the ground side
H Delivery conductor
I Total current
IF Fault current
IH Current through delivery conductor
IR Current through return conductor
MEH Voltage-side measuring equipment
MEL Ground-side measuring equipment
MUX Multiplexer
R1 Resistor
R2 Resistor
R3 Resistor
RH Low-ohmic current-sense resistor
RL Low-ohmic current-sense resistor
R Return conductor
ST Voltage divider
SYNC Synchronization signal
TEH Thermocouple on the High side
TEL Thermocouple on the Low side
TH Temperature of the current sense resistor on the High side
TL Temperature of the current sense resistor on the Low side
TSH Temperature sensor on the High side
TSL Temperature sensor on the Low side
U0 Overall voltage
UH Voltage drop over current sense resistor RH
UL Voltage drop over current sense resistor RL
U_{REFH} Voltage reference for the High side
U_{REFL} Voltage reference for the Low side
V Consumer

1. A differential current sensor adapted for measuring a differential current between a first electric current through a delivery conductor and a second electric current through a return conductor, in particular for a direct-current power supply system, comprising:
a) a low-ohmic first current-sense resistor for measuring the first electric current through the delivery conductor, wherein the first current-sense resistor is arranged in the delivery conductor and the first electric current flows through the first current-sense resistor,
b) a first measuring device with a first measuring transducer for measuring a first voltage drop over the first current-sense resistor,
c) a first voltage reference for calibrating the first measuring device,
d) a low-ohmic second current-sense resistor for measuring the second electric current through the return conductor, wherein the second current-sense resistor is arranged in the return conductor and the second electric current flows through the second current-sense resistors,
e) a second measuring device with a second measuring transducer for measuring a second voltage drop over the second current-sense resistor,
f) a second voltage reference for calibrating the second measuring device, wherein
g) the first measuring transducer successively measures both the first voltage drop and the first voltage reference, and
h) the second measuring transducer successively measures both the second voltage drop over the second current current-sense resistor and the second voltage reference.

2. The differential current sensor according to claim 1, wherein
a) a voltage divider comprising a plurality of resistors is connected between the delivery conductor and the return conductor,
b) the first voltage reference is formed by a first voltage tapping point on the voltage divider, and
c) the second voltage reference is formed by a second voltage tapping point on the voltage divider.

3. The differential current sensor according to claim 2, wherein
a) the voltage divider is dimensioned in such a manner that the first voltage drop over the first current-sense resistor is of a same order of magnitude as the first voltage reference, and
b) the voltage divider is dimensioned in such a manner that the second voltage drop over the second current-sense resistor is of a same order of magnitude as the second voltage reference.

4. The differential current sensor according to claim 2, wherein
a) the voltage divider has a series circuit comprising a voltage-side first resistor, a central second resistor and a ground-side third resistor,
b) the central second resistor has a substantially higher resistance value than the voltage-side first resistor and than the ground-side third resistor,
c) the first voltage tapping point for the first voltage reference is connected to the first measuring device between the voltage-side first resistor and the central resistor, and
d) the second voltage tapping point for the second voltage reference is connected to the second measuring device between the ground-side third resistor and the central resistor.

5. The differential current sensor according to claim 4, wherein a resistance value at the voltage-side first resistor of the voltage divider and at the ground-side third resistor of the voltage divider essentially has the same temperature dependence.

6. The differential current sensor according to claim 2, wherein
a) the voltage divider has a ceramic support, and
b) the resistors of the voltage divider are applied as homogeneous resistance material onto the ceramic support.

7. The differential current sensor according to claim 1, further comprising an electronic evaluation unit, which is connected to the first measuring device and to the second measuring device and determines the differential current as a function of the first voltage drop and the second voltage drop.

8. The differential current sensor according to claim 7, wherein the evaluation unit transmits at least one of a triggering signal and a clock signal to the first measuring device and to the second measuring device and as a result triggers a simultaneous measurement by the first measuring device and by the second measuring device.

9. The differential current sensor according to claim 7, wherein
a) a first thermocouple is provided for measuring a first temperature difference over the first current-sense resistor,
b) the first measuring device or the evaluation unit calculates a first thermoelectric potential as a function of the first temperature difference, which drops over the first current-sense resistor,
c) the first measuring device or the evaluation unit takes account of the first thermoelectric potential during the current measurement,
d) a second thermocouple is provided for measuring a second temperature difference over the second current-sense resistor,
e) the second measuring device or the evaluation unit calculates a second thermoelectric potential as a function of the second temperature difference, which drops over the second current-sense resistor, and
f) the second measuring device or the evaluation unit takes account of the second thermoelectric potential during the current measurement.

10. The differential current sensor according to claim 7, wherein
a) a first temperature sensor is provided for measuring a first temperature of the first current-sense resistor,
b) the first measuring device or the evaluation unit calculates a temperature-related change of the resistance value of the first current-sense resistor as a function of the first temperature,
c) the first measuring device or the evaluation unit takes account of the temperature-related change of the resistance value during the current measurement,
d) a second temperature sensor is provided for measuring a second temperature of the second current-sense resistor,
e) the second measuring device or the evaluation unit calculates a temperature-related change of the resistance value of the second current-sense resistor as a function of the second temperature, and
f) the first measuring device or the evaluation unit takes account of the temperature-related change of the resistance value during the current measurement.

11. The differential current sensor according to claim 7, further comprising
a) a galvanically separated first data line between the first measuring device and the evaluation unit for transmitting at least one of the following signals from the first measuring device to the evaluation unit:
a1) the first voltage drop,
a2) a triggering signal,
a3) the first temperature difference, and
a4) the first temperature, and
b) a galvanically separated second data line between the second measuring device and the evaluation unit for transmitting at least one of the following signals from the second measuring device to the evaluation unit:
b1) the second voltage drop,
b2) a triggering signal, and
b3) the second temperature difference, and
b4) the second temperature.

12. The differential current sensor according to claim 1, wherein the first current-sense resistor is thermally connected to the second current-sense resistor by way of an electrically insulating, but thermally conductive heat bridge, in order to minimize a temperature difference between the two current-sense resistors.

13. The differential current sensor according to claim 1, wherein
a) the first current-sense resistor and the second current-sense resistor have the same resistance value, and/or
b) the resistance value at the first current-sense resistor and at the second current-sense resistor essentially has the same temperature dependence.

14. The differential current sensor according to claim 1, wherein
a) the first measuring device has a first multiplexer, wherein the first measuring transducer, successively measures the first voltage drop over the first current-sense resistor and the first voltage reference by way of the first multiplexer,
b) the second measuring device has a second multiplexer, wherein the second measuring transducer successively measures the second voltage drop over the second current-sense resistor and the second voltage reference by way of the second multiplexer.

15. The differential current sensor according to claim 1, wherein the differential current sensor outputs at least one of the following values:
a) the differential current,
b) a total voltage which drops between the delivery conductor and the return conductor,
c) the first electric current or a current value derived therefrom,
d) the second electric current or a current value derived therefrom,
e) the first temperature difference or a value derived therefrom,
f) the second temperature difference or a value derived therefrom,
g) the first temperature or a value derived therefrom, and
h) the second temperature or a value derived therefrom.

16. A power supply system with a differential current sensor according to claim 1.

17. The power supply system according to claim 16, wherein the power supply system is a direct-current power supply system.

18. The power supply system according to claim 17, wherein the power supply system is a motor vehicle electrical system.
